(19) United States
(12) Patent Application Publication
(10) Pub. No.: US 2015/0371684 A1
(43) Pub. Date: Dec. 24, 2015

(54) ULTRA HIGH CAPACITY SSD

(71) Applicant: NXGN DATA, INC., Irvine, CA (US)

(72) Inventor: Richard Mataya, Rancho Santa Margarita, CA (US)

(21) Appl. No.: 14/741,921

(22) Filed: Jun. 17, 2015

Related U.S. Application Data
(60) Provisional application No. 62/013,903, filed on Jun. 18, 2014.

(51) Int. Cl. G11C 5/06

(52) U.S. Cl. CPC G11C 5/06

(57) ABSTRACT

The solution described here is a modular, very high capacity SSD realization. The SSD design and modular memory elements renders the SSD both factory and field serviceable as well as facilitating just-in-time manufacturing processes. In the case of improving the factory reparability of the drive, the modular memory elements can be tested (and repaired) independent of the main SSD. This reduces costs and risks in the manufacturing and repair process. The manufacturing process is improved by allowing for the staging of elements, such as variable sized memory cards, to facilitate last minute assembly and test of the product. By separating the assembly and test of the expensive and complex main board, with its FPGA control, power and memory elements (DRAM), from the simpler memory card, the timing to delivery is improved, the risk is reduced, and inventory costs are minimized. From a field-repairable perspective, the solution is conceived such that a failing storage element can be replaced in the field and the lost memory image automatically rebuilt on the next power up using the integrated redundancy (RAID) capability while continuing to run host initiated commands, albeit at a reduced performance level.

### CROSS-REFERENCE TO RELATED APPLICATION(S)

The present application claims priority to and the benefit of U.S. Provisional Application No. 62/013903, filed Jun. 18, 2014, entitled “ULTRA HIGH CAPACITY SSD”, the entire content of which is incorporated herein by reference.

### FIELD

One or more aspects of embodiments according to the present invention relate to an ultra high capacity SSD.

### BACKGROUND

Most SSDs today are not designed to be modular. This is usually a result of an SSD's low capacity, low number of supported memory devices, relatively low complexity and attempts to maximize cost savings. With the advent of very high capacity SSDs that can independently control hundreds or thousands of memory devices, a modular approach must be embraced to facilitate component procurement, manufacturing, ease of test, and to mitigate the potential for die or device failures in the field.

One patent that discloses a modular SSD approach to address expandability and support for a solution is 2009/0063895 A1. This approach identifies spare locations and intelligence co-located with the memory elements, and is primarily defined for expanding the capacity of an SSD device and manually repairing “worn-out” memory elements by copying them off an SSD device, replacing the memory element with power removed, and copying the data back to the new storage element before reusing.

Costs associated with this type of product are very high, and the incremental increase in cost to add connections are significantly outweighed by the ability to repair and replace units in both the factory and the field. Also, using a mass produced and already proven interconnection solution like the M.2 reduces risk and simplifies integration. Concerns over robustness, signal integrity, interference and complexity are significantly reduced.

### SUMMARY

Aspects of embodiments of the present disclosure are directed toward an ultra high capacity SSD.

### BRIEF DESCRIPTION OF THE DRAWINGS

These and other features and advantages of the present invention will be appreciated and understood with reference to the specification, claims and appended drawings wherein:

FIG. 1 is a logical diagram of an ultra high capacity SSD, according to an embodiment of the present invention;

FIG. 2 is a logical diagram of an ultra high capacity SSD, according to an embodiment of the present invention;

FIG. 3 is a drawing of an instantiation of the solution, according to an embodiment of the present invention;

FIG. 4 is a drawing of an instantiation of the solution, according to an embodiment of the present invention;

FIG. 5 is a flow chart of an assembly process, according to an embodiment of the present invention;

FIG. 6 is a flow chart of a recovery process, according to an embodiment of the present invention;

FIG. 7 is a pictorial diagram of a recovery process, according to an embodiment of the present invention;

FIG. 8 is a diagram of a manner of storage, according to an embodiment of the present invention;

FIG. 9 is a diagram of a modular storage element, according to an embodiment of the present invention; and

FIG. 10 is a diagram of a memory card, according to an embodiment of the present invention.

### DETAILED DESCRIPTION

The detailed description set forth below in connection with the appended drawings is intended as a description of exemplary embodiments of a Ultra High Capacity SSD provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

Keywords

DRAM—Dynamic Random Access Memory

FPGA—Field Programmable Gate Array

JIT—Just in Time

Modular

RAID—Redundant Array of Inexpensive Drives/Devices

SoC—System on a Chip

SSD—Solid State Drive

This patent application will describe an SSD architecture that is “common”, in that it uses a standard storage protocol, uses either an FPGA or SoC to incorporate the control electronics, is composed of a centralized SSD controller with DRAM and Flash (NAND EEPROM), and emulates the behavior of storage devices like hard disk drives and other solid state drives. The key differences are in how the unit is assembled and the ability to service the device in the factory and in the field.

### Details of Various Embodiments

The SSD products for ultra-high capacity applications are expected to be employed in a number of form factors and tuned for several different applications. They employ standard storage interface protocols, such as SAS or PCIe/NVMe. They are housed in standard storage form factors. Examples are a standard 3.5-inch LFF product with a 26.1 mm height can be realized using the SFF-8639 connector that will allow for replacing HDDs in cold storage applications. Using the SFF standard, a dual-port solution can be realized to increase the overall system reliability and availability. Additional products may use a standard PCIe card form factor, most likely in the full-height, full length (FH-FL) card outline for super high capacity solutions. Other instantiations and moderate capacity solutions might be realized in shorter (FH-HL) outlines.

The storage medium used to realize this product could be current and next generation flash (NAND EEPROM) devices compliant with the ONFI and Toggle interface standards or other similar or future NVM technology. The devices are typically a high density, block addressable and erasable element that is particularly well suited for block storage applications. As the program and read timing is not symmetric, system level techniques are needed to optimize and flatten the product performance. Because of the high cost and density of the storage medium, system level techniques will be used to augment the endurance, reliability and serviceability of the media, allowing use of lower cost TLC components and lowering the manufacturing and usage costs of the final product.

This is the key difference between standard SSDs and this solution: the extremely high number of memory components being used in conjunction with a single controller. To offset the risks in yield during manufacturing and high cost of field failures, a modular approach to the design is embraced.

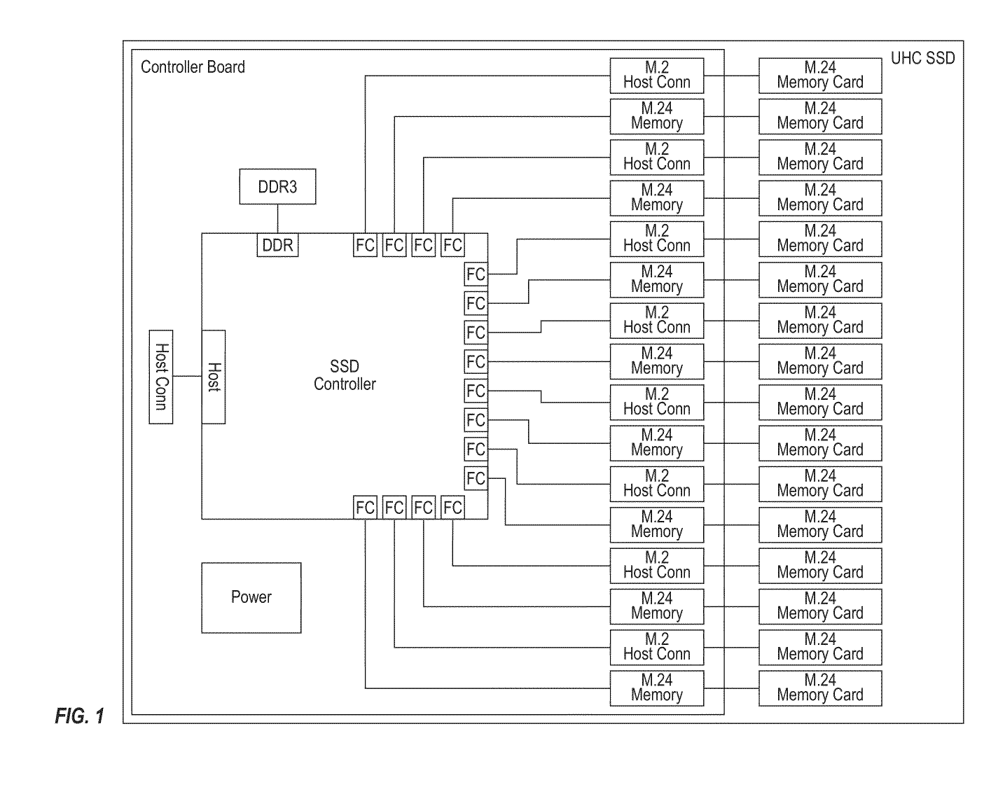

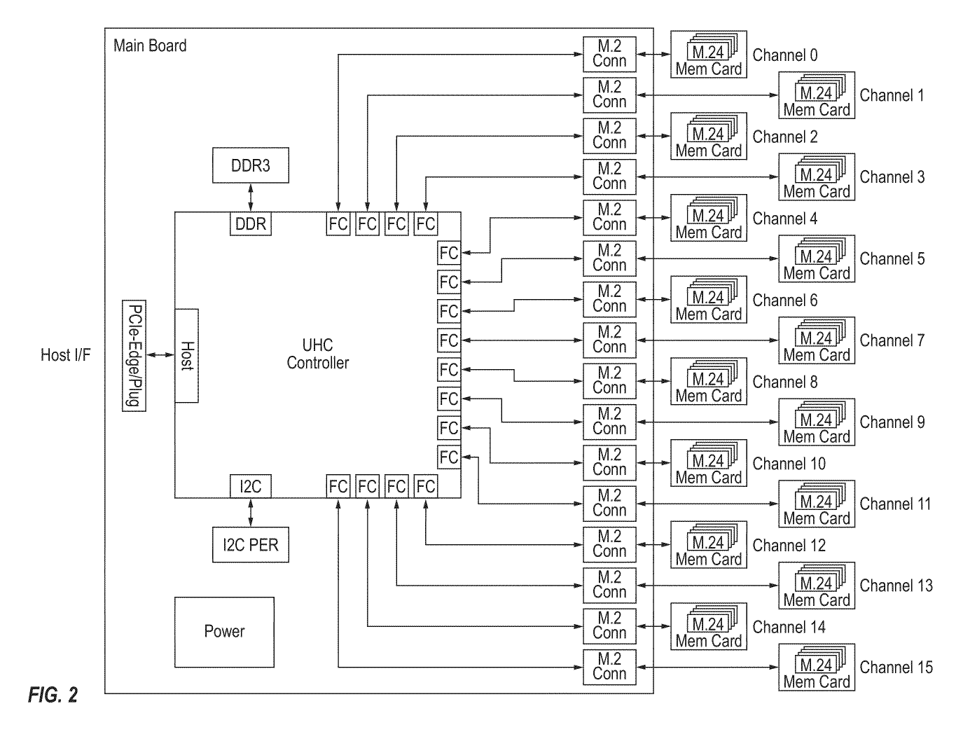

The diagrams of FIGS. 1 and 2 illustrates the logical design of the UHC SSD, which is composed of a main board with a controller, interface connection to the host, suitable power, and individual connections for each channel of the memory elements. The connections are expected to be proven for reliability, signal integrity and serviceability, leveraging existing components already proven for this type of application. The memory elements are realized on individual memory cards, labelled M.24 in the diagram, and hold all of the storage elements required for each memory channel.

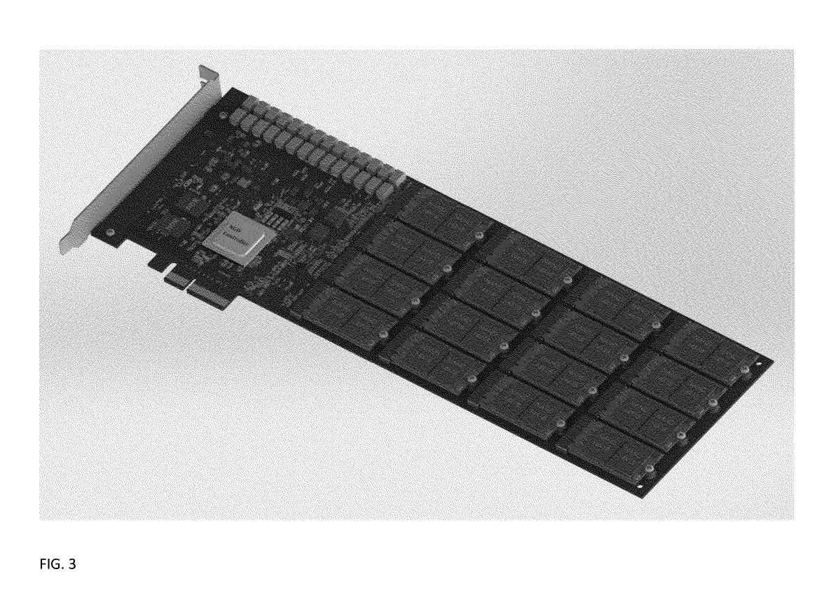

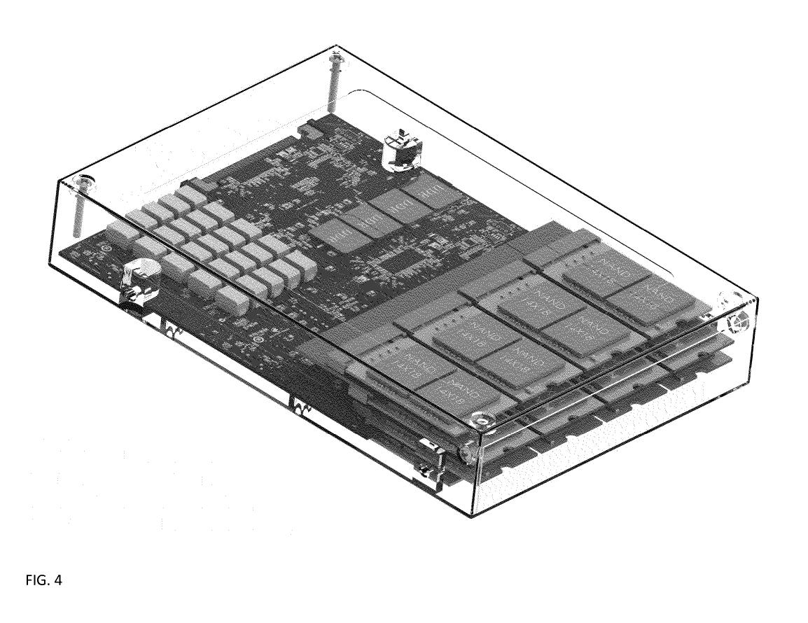

Several possible instantiations of the solution are depicted immediately following the logical diagrams of the product. See FIGS. 3-4.

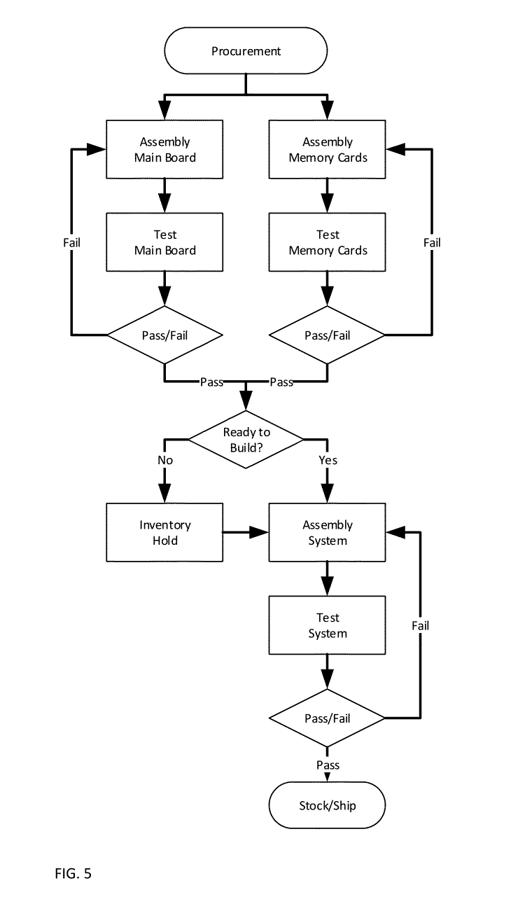

Assembly and testing of each component, those being the UHC controller and the M.24 memory cards, can be done independently. Any failure of a component in the assembly and test process can be easily replaced, thus avoiding a large inventory charge while debug and repair occurs. The following flow chart highlights the assembly process. See FIG. 5.

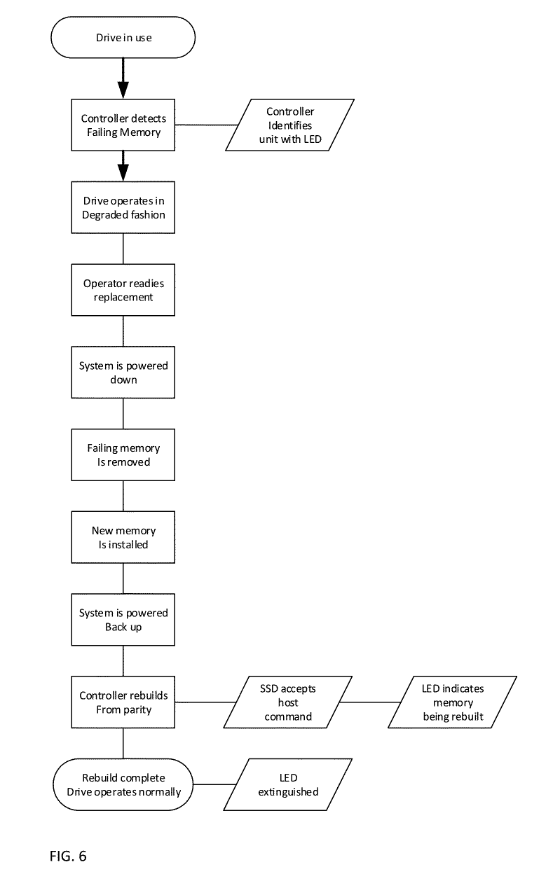

The architecture of the SSD controller is implemented such that the failure of any memory card does not impact the ability to retrieve any and all data from the media. A parity stripe is employed that results in sufficient redundancy being available so that the failure or removal of any channel, represented by a memory storage element or card, can be overcome and valid data returned to the host on request, or the data can be reconstructed and replaced on media once it recovers or is replaced. The flow chart below describes one method of this recovery. See FIG. 6.

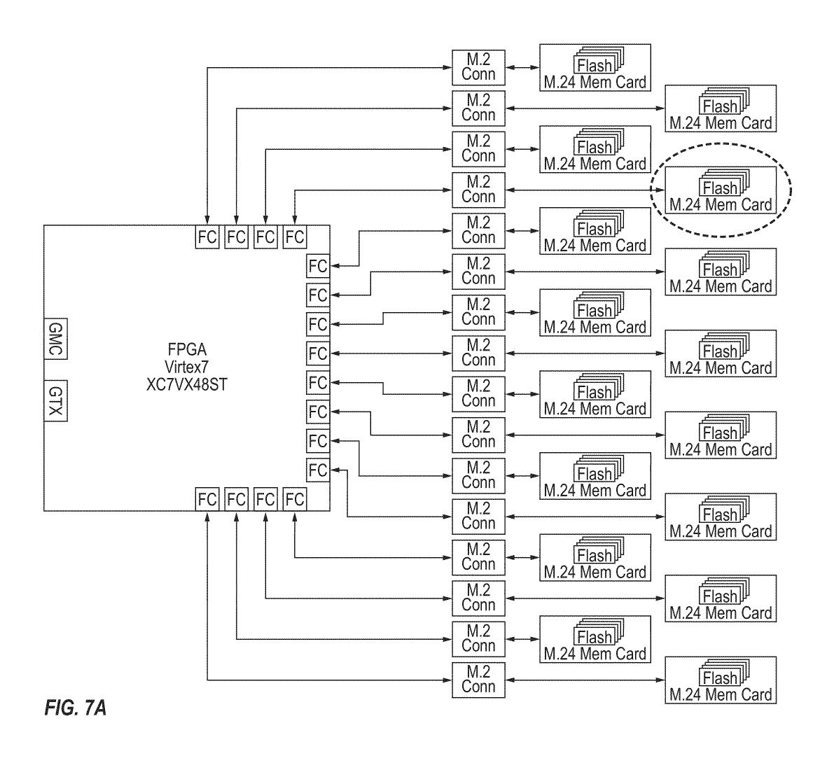

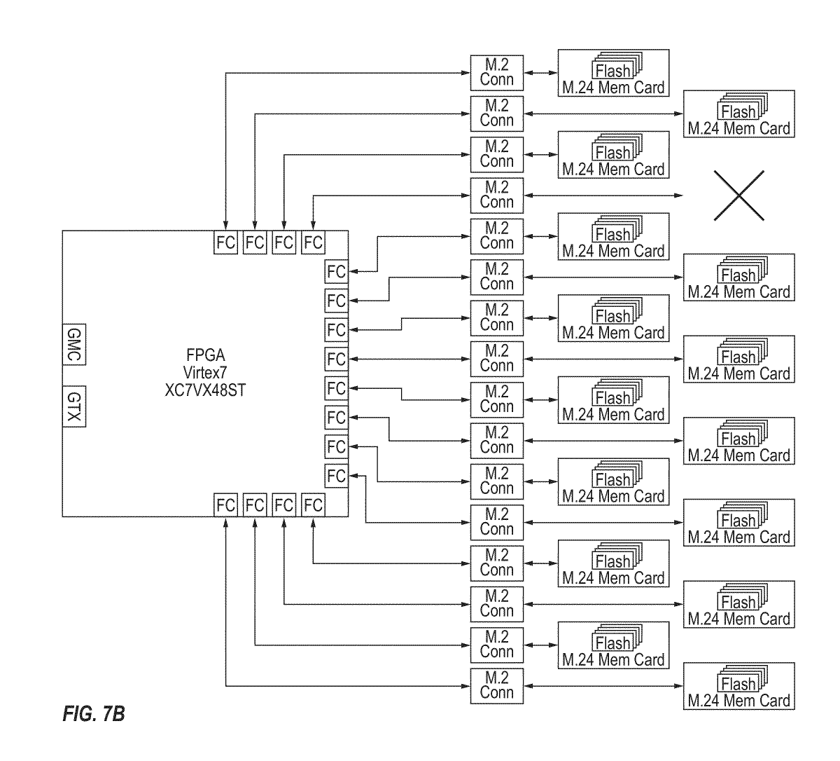

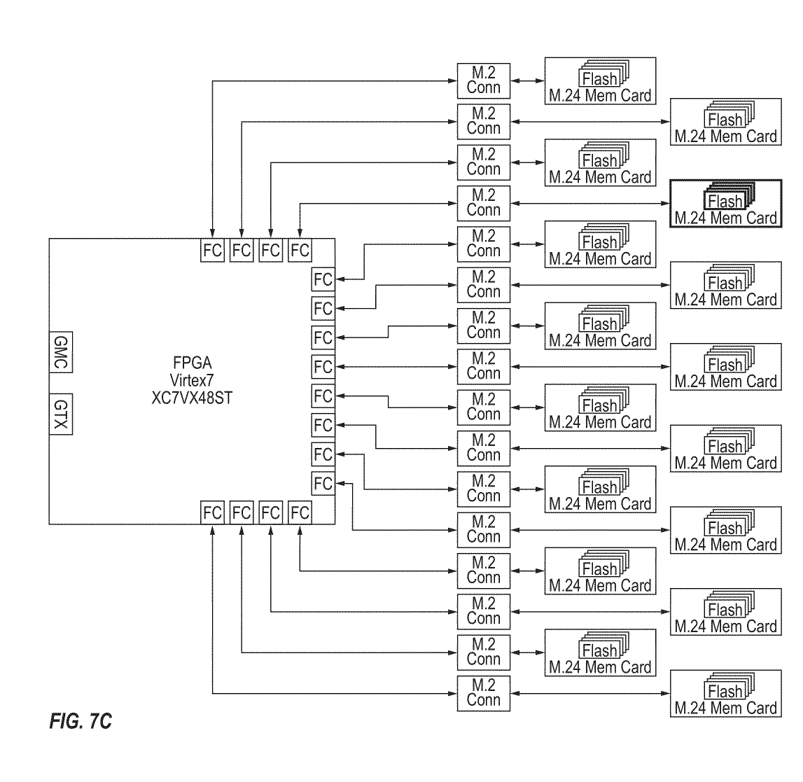

The diagram below describes this same process pictorially. See FIG. 7.

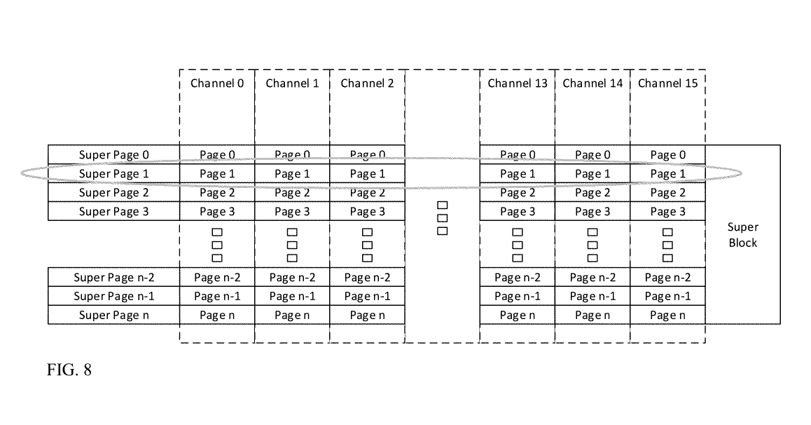

To facilitate the modularity of the design and ability to replace whole channels, the data must be striped across all channels in a regular manner and include some method of reconstructing all data that was lost. The manner that the data is stored is shown in the diagram below. Effectively, as data is stored on the media, it is written in stripes to a page in every channel. See FIG. 8.

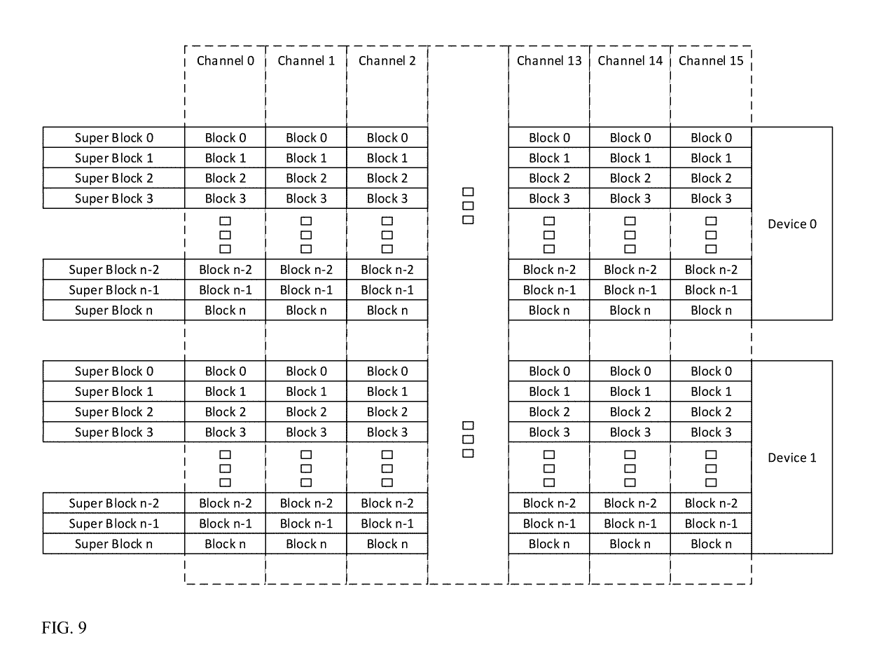

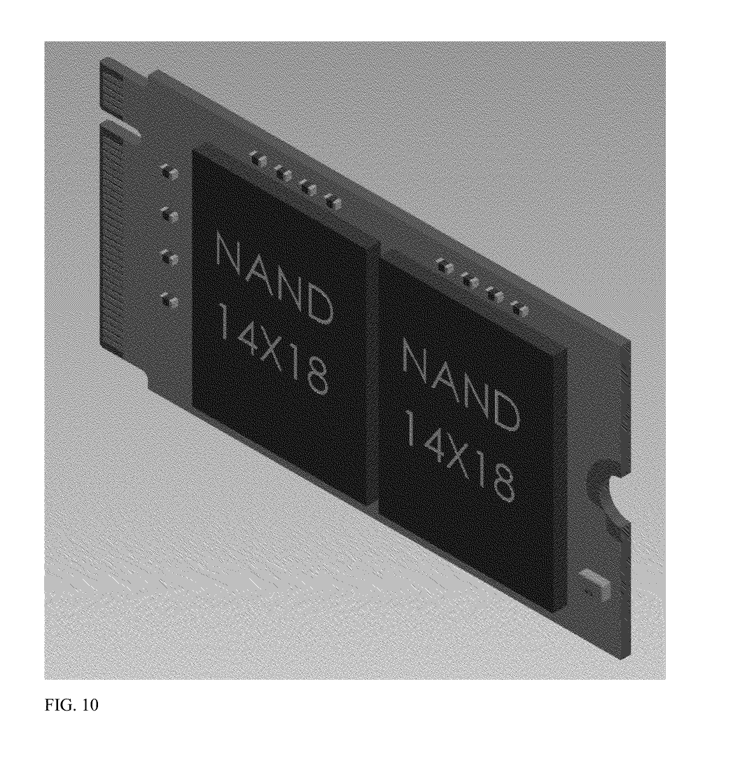

The pages that are part of the same stripe across the channels are labeled a “Super Page”, but may also be referred to as a “Page Stripe”. In flash, many pages are combined into the smallest erasable unit called a block, and all the Super Stripes would then be combined into a Super Block. Many blocks are combined to form a device, and many devices may be combined on a single modular storage element, or M.24 memory card. See FIGS. 9 and 10.

### Advantages/Benefits of Embodiments of the Invention

Modular design and architectural features of the product facilitate ease of manufacture through:

1. Independent manufacture of the modular elements: memory cards and main cards

2. Reuse of the modular elements across multiple product lines

3. Independent testing of the modular elements

4. Repair and retest of each element without impacting the workflow and shipment of the final system

Modular design and architectural features of the product that facilitate the field reliability and robustness by:

1. Continued operation of the system (with degraded performance) if a storage element fails

2. Simplified replacement and automatic recovery of the lost information using the integrated redundancy and modularity of the solution

3. Ability to reduce or scale the memory capacity as needed on a failure in a storage element

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, ^{“}upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art. As used herein, the term “major component” means a component constituting at least half, by weight, of a composition, and the term “major portion”, when applied to a plurality of items, means at least half of the items.

As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Although exemplary embodiments of a Ultra High Capacity SSD have been specifically described and illustrated herein, many modifications and variations will be apparent to those skilled in the art. Accordingly, it is to be understood that a Ultra High Capacity SSD constructed according to principles of this invention may be embodied other than as specifically described herein. The invention is also defined in the following claims, and equivalents thereof

What is claimed is:

1. An SSD storage device that uses modular storage elements to maintain a level of flexibility and reparability.

2. The SSD of claim 1 where control of the storage elements is wholly contained on a main board.

3. The SSD of claim 2 that supports a standard storage interface protocols such as PCIe, NVMe or SCSI Express.

4. The storage elements are modular and removable with an electronic coupling mechanism.

5. The electronic coupling is through a mechanical connector.

6. The mechanical connector and mechanical outline of the storage element are similar to the M.2 form factor, though the pin definitions and protocol are not.

7. The modular storage elements are composed of basic mass memory elements such as flash or other relevant NVM as well as discrete components—“intelligence” is wholly contained in the main controller.

8. The modular storage elements represent channels on the SSD that are protected by parity (RAID) such that the failure or removal of one element does not prohibit proper operation of the memory, though at a degraded performance level.

9. The parity protection (RAID) allows for the rebuilding of the lost memory and return to full performance levels with replacement of a failing or missing memory.

10. The modular design of the product allows for independent manufacture and testing of the main parts of the SSD.

11. Independent manufacture (from claim 10) allows for more timely use of components and interchange of the components between different final products, which both ultimately go towards reducing inventory costs.

12. Independent testing (from claim 10) of the elements reduces the manufacturing risk associated with a failure in the complex control electronics of the main board or the high number of interconnections on the memory elements.
